(19) United States
(12) Patent Application Publication
(10) Pub. No.: US 2022/0100044 A1
(43) Pub. Date: Mar. 31, 2022

(54) DISPLAY PANEL, DISPLAY DEVICE, AND MASK

(71) Applicant: Xiamen Tianma Microelectronics Co., Ltd., Xiamen (CN)

(72) Inventors: Kunfeng ZHANG, Xiamen (CN); Zhuo DENG, Xiamen (CN); Hao WU, Xiamen (CN); Poping SHEN, Xiamen (CN)

(73) Assignee: Xiamen Tianma Microelectronics Co., Ltd., Xiamen (CN)

(21) Appl. No.: 17/549,000

(22) Filed: Dec. 13, 2021

(30) Foreign Application Priority Data
Sep. 30, 2021 (CN) 202111165558.1

(51) Int. Cl. G02F 1/1362

(52) U.S. Cl. CPC G02F 1/136286

(57) ABSTRACT

Provided are a display panel, a display device, and a mask. The display panel includes an array substrate. The array substrate includes a base substrate and first wires and second wires located on one side of the base substrate. The orthographic projections of the first wires on a plane where the base substrate is located intersect the orthographic projections of the second wires on the plane where the base substrate is located; and wire widths of the first wires at intersections are smaller than at least part of wire widths of the first wires at positions other than the intersections, and/or wire widths of the second wires at intersections are greater than at least part of wire widths of the second wires at positions other than the intersections.

### CROSS-REFERENCE TO RELATED APPLICATIONS

This application claims priority to Chinese patent application No. 202111165558.1 filed with the China National Intellectual Property Administration (CNIPA) on Sep. 30, 2021, the disclosure of which is incorporated herein by reference in its entirety.

### TECHNICAL FIELD

Embodiments of the present disclosure relate to the field of display technologies and, in particular, to a display panel, a display device, and a mask.

### BACKGROUND

A display panel is a main component for implementing the display function of an electronic device. A liquid crystal display panel is a type of display panel commonly used today. The liquid crystal display panel includes a display region and a bezel region surrounding the display region. With the development of liquid crystal display technologies, users have higher and higher requirements for the performance and appearance of the liquid crystal panel, resulting in a smaller bezel region of the liquid crystal display panel.

The bezel region of a display device is provided with wires, such as a fan-out region, configured to provide drive signals for pixel units in the display region. Since a wire width of the bezel region is relatively small, and part of wires inevitably intersect up and down, there is a risk of wire breakage at an intersection.

### SUMMARY

The present disclosure provides a display panel, a display device, a manufacturing method, and a mask so as to prevent the wire breakage caused by a too small wire width due to the exposure issue and effectively ensure the wire quality, so that the display panel can work normally.

The present disclosure provides a display panel including an array substrate. The array substrate includes a base substrate, and first wires and second wires located on one side of the base substrate, and a film layer where the first wires are located is located between the base substrate and a film layer where the second wires are located.

The orthographic projections of the first wires on a plane where the base substrate is located intersect the orthographic projections of the second wires on the plane where the base substrate is located; and wire widths of the first wires at intersections are smaller than at least part of wire widths of the first wires at positions other than the intersections, and/or wire widths of the second wires at intersections are greater than at least part of wire widths of the second wires at positions other than the intersections.

The intersections are positions where the orthographic projections of the first wires on the plane where the base substrate is located intersect the orthographic projections of the second wires on the plane where the base substrate is located.

The present disclosure further provides a display device including the display panel according to any embodiment of the present disclosure.

The present disclosure further provides a manufacturing method of a display panel. The manufacturing method is configured to manufacture any one of display panels according to the embodiments of the present disclosure. The manufacturing method includes steps described below.

The base substrate is provided and the first wires are formed on the base substrate.

The second wires are formed in the film layer where the first wires are located. The orthographic projections of the first wires on the plane where the base substrate is located intersect the orthographic projections of the second wires on the plane where the base substrate is located; and the wire widths of the first wires at the intersections are smaller than the at least part of the wire widths of the first wires at the positions other than the intersections, and/or the wire widths of the second wires at the intersections are greater than the at least part of the wire widths of the second wires at the positions other than the intersections.

The intersections are positions where the orthographic projections of the first wires on the plane where the base substrate is located intersect the orthographic projections of the second wires on the plane where the base substrate is located.

The present disclosure further provides a mask configured for manufacturing of the first wires or the second wires in any one of display panels according to the embodiments of the present disclosure. The mask includes a light-transmissive region, and the light-transmissive region includes a first light-transmissive subregion and a second light-transmissive subregion.

The first light-transmissive subregion is configured for manufacturing of the first wires at the intersections, and the second light-transmissive subregion is configured for manufacturing of the first wires at the positions other than the intersections; and a width of the first light-transmissive subregion in a direction perpendicular to an extension direction of the first light-transmissive subregion is smaller than a width of at least part of the second light-transmissive subregion in a direction perpendicular to an extension direction of the second light-transmissive subregion.

Alternatively, the first light-transmissive subregion is configured for manufacturing of the second wires at the intersections, and the second light-transmissive subregion is configured for manufacturing of the second wires at the positions other than the intersections; and a width of the first light-transmissive subregion in a direction perpendicular to an extension direction of the first light-transmissive subregion is greater than a width of at least part of the second light-transmissive subregion in a direction perpendicular to an extension direction of the second light-transmissive subregion.

### BRIEF DESCRIPTION OF DRAWINGS

FIG. 1 is a structure diagram of an existing display panel;

FIG. 2 is a partial enlarged view of a fan-out region of the display panel shown in FIG. 1;

FIG. 3 is a section view taken along AN of the display panel of FIG. 2;

FIG. 4 is a partial enlarged view of a display panel according to an embodiment of the present disclosure;

FIG. 5 is a partial section view taken along BB′ of the display panel of FIG. 4;

FIG. 6 is a partial enlarged view of another display panel according to an embodiment of the present disclosure;

FIG. 7 is a partial enlarged view of another display panel according to an embodiment of the present disclosure;

FIG. 8 and FIG. 9 are structure diagrams of another two display panels according to an embodiment of the present disclosure;

FIG. 10 is a section view taken along the direction perpendicular to the extension direction of fan-out wires of the display panel of FIG. 8;

FIG. 11 is a section view taken along the direction perpendicular to the extension direction of fan-out wires of the display panel of FIG. 9;

FIG. 12 is a structure diagram of another display panel according to an embodiment of the present disclosure;

FIG. 13 is a structure diagram of another display panel according to an embodiment of the present disclosure;

FIG. 14 is a partial enlarged view of the fan-out region of FIG. 13;

FIG. 15 and FIG. 16 are two section views taken along the extension direction of fan-out wires of the display panel of FIG. 12;

FIG. 17 is a section view of another display panel according to an embodiment of the present disclosure;

FIG. 18 is a section view of another display panel according to an embodiment of the present disclosure;

FIG. 19 is a structure diagram of another display panel according to an embodiment of the present disclosure;

FIG. 20 is a structure diagram of another display panel according to an embodiment of the present disclosure;

FIG. 21 is a structure diagram of another display panel according to an embodiment of the present disclosure;

FIG. 22 is a partial enlarged view of a bezel region of the display panel of FIG. 21;

FIG. 23 is a structure diagram of another display panel according to an embodiment of the present disclosure;

FIG. 24 and FIG. 25 are structure diagrams of two display devices according to an embodiment of the present disclosure; and

FIG. 26 is a flowchart of a manufacturing method of a display panel according to an embodiment of the present disclosure.

### DETAILED DESCRIPTION

The present disclosure is further described hereinafter in detail in conjunction with drawings and embodiments. It is to be understood that embodiments described hereinafter are intended to explain the present disclosure and not to limit the present disclosure. Additionally, it is to be noted that for ease of description, only part, not all, of structures related to the present disclosure are illustrated in the drawings.

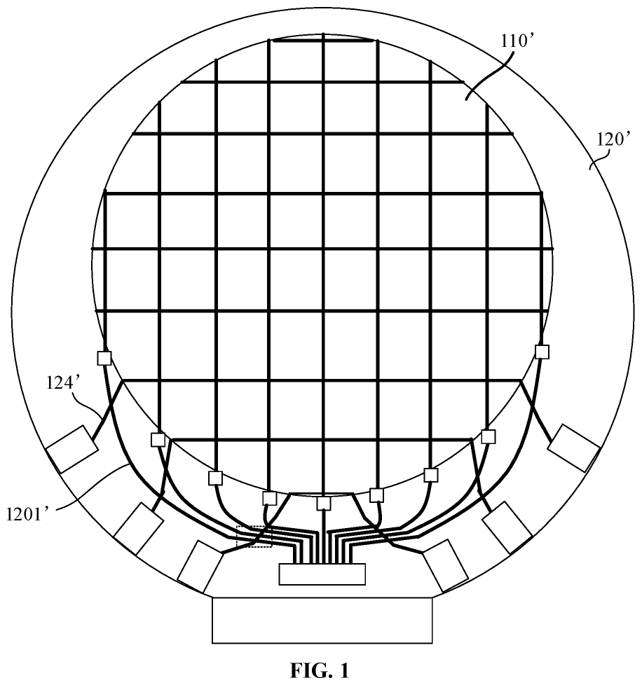

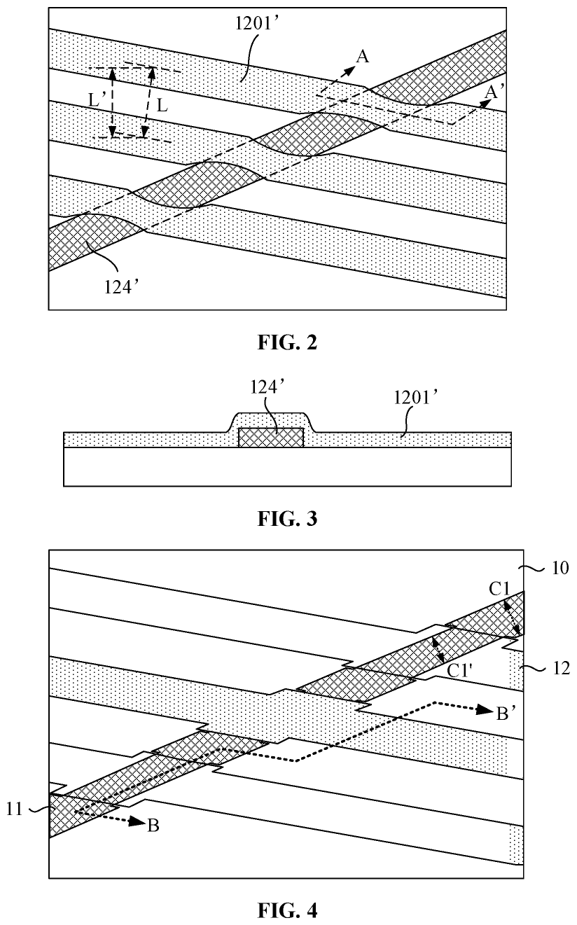

FIG. 1 is a structure diagram of an existing display panel, FIG. 2 is a partial enlarged view of a fan-out region of the display panel shown in FIG. 1, and FIG. 3 is a section view taken along AA′ of the display panel of FIG. 2. Referring to FIGS. 1 to 3, in an existing onboard display product, fan-out wires 1201′ of a bezel region 120′ generally extend obliquely and are arranged horizontally and sequentially. The overall longitudinal height of the fan-out region is positively correlated with the center spacing between wires within the fan-out region. As shown in FIG. 2, the greater the center spacing L between wires is, the greater the component L′ in a longitudinal direction is, and for the entire fan-out region including a plurality of fan-out wires, the larger the area of the fan-out region in the longitudinal direction is. Because the fan-out region occupies the largest proportion of the entire lower bezel, in order for the onboard display to achieve the design of a narrow bezel, it is necessary to compress the center spacing between wires in the fan-out region as much as possible, and wire widths of the fan-out wires 1201′ should be designed as minimum as possible.

In addition to the fan-out wires 1201′, the bezel region 120′ is further provided with other signal wires, for example, scan signal lines 124′. The projections of the scan signal lines 124′ intersect the projections of the fan-out wires 1201′. Therefore, when manufacturing the fan-out wires 1201′, the fan-out wires 1201′ are partially overexposed due to the retroreflective effect of the scan signal lines 124′ whose projections below intersect the projections of the fan-out wires 1201′, so that wire widths of the fan-out wires finally formed at these intersections become smaller than wire widths of the fan-out wires at other positions.

On this basis, in response to the fan-out wires having very small wire widths being incorporated with dust particles during a manufacturing process, the fan-out wires are extremely easy to break. Moreover, the smaller the wire width of a wire at an intersection is, the higher the electrical impedance is, and excessive heat is easily generated and fuses the wire during a working process. In addition, because of the wires intersecting up and down, as shown in FIG. 3, the presence of a wire in a lower layer causes a surface to appear partially convex, so that a wire in an upper layer is not entirely on the same plane. In other words, the wire located in the upper layer needs to across the convex formed by the wire in the lower layer to produce a climbing form. Since the film layer of the wire is generally formed by deposition, the wire in the upper layer at this climbing position also has the risk of wire breakage due to an insufficient deposition amount when manufacturing.

Based on the design of the wire widths of the fan-out wires 1201′ is already at a relatively small level, the wire widths of the fan-out wires 1201′ become smaller due to the above-described issue that the exposure amount is not accurate enough. That is, as described in the background section, the exposure issue causes an increase in the risk of breakage of some wires in the display panel, which can affect normal working of the display panel.

An embodiment of the present disclosure provides a display panel. The display panel includes an array substrate. The array substrate includes a base substrate and first wires and second wires located on one side of the base substrate. A film layer where the first wires are located is located between the base substrate and a film layer where the second wires are located. The orthographic projections of the first wires on a plane where the base substrate is located intersect the orthographic projections of the second wires on the plane where the base substrate is located. Wire widths of the first wires at intersections where the orthographic projections of the first wires on the plane where the base substrate is located intersect the orthographic projections of the second wires on the plane where the base substrate is located are smaller than at least part of wire widths of the first wires at positions other than the intersections, and/or wire widths of the second wires at intersections where the orthographic projections of the first wires on the plane where the base substrate is located intersect the orthographic projections of the second wires on the plane where the base substrate is located are greater than at least part of wire widths of the second wires at positions other than the intersections.

The first wires and the second wires are substantially located in different film layers of the array substrate. The second wires are located in the upper layer of the first wires, and the projections of the second wires intersect the projections of the first wires. It is to be understood that in response to the second wires being manufactured by using a photolithography technique, due to the retroreflective effect of the first wires during an exposure process, exposure of the second wires at the intersections is excessive, thereby causing the wire widths of the second wires at the intersections being smaller than the wire width of a design value or wire widths at other positions without overexposure. The embodiments of the present disclosure are substantially based on the issue of overexposure, and a wire width design value of the first wires and/or the second wires at the intersections is appropriately adjusted, so that even if the wire width changes due to the exposure issue during an actual manufacturing process, a change amount can be compensated by using the design value, so as to avoid the wire breakage caused by an actually formed wire width of a wire being too small.

The embodiments of the present disclosure provide various alternative schemes. The wire widths of the first wires at the intersections are disposed to be smaller than at least part of wire widths of the first wires at positions other than the intersections. The essence is to appropriately reduce the wire widths of the first wires located in the lower layer at the intersections. In this case, the retroreflective capability of the first wires located in the lower layer is reduced due to the reduced wire widths, so an exposure influence on the second wires located in the upper layer is reduced. To some extent, the wire widths of the second wires located in the upper layer at the intersections can be avoided to decrease, thereby preventing the second wires from being broken. The wire widths of the second wires at the intersections are disposed to be greater than at least part of wire widths of the second wires at positions other than the intersections. The essence is to appropriately increase the wire widths of the second wires located in the upper layer at the intersections. In this case, even if the first wires in the lower layer appears a retroreflective phenomenon during the exposure process, the wire widths of the second wires at the intersections in the upper layer can be decreased to some extent, but the wire widths of the second wires finally formed can still be at a relatively large level, so that the occurrence of a wire breakage situation can be prevented. It is to be understood that when the scheme of increasing the wire widths of the second wires at the intersections and the scheme of decreasing the wire widths of the first wires at the intersections are used at the same time, the above-described wire breakage issue caused by the overexposure can be more effectively avoided and the normal working of the display panel can be ensured.

The above is the core concept of the present disclosure, and technical schemes in the embodiments of the present disclosure will be described clearly and completely in conjunction with the drawings in the embodiments of the present disclosure. Based on embodiments of the present disclosure, all other embodiments obtained by those of ordinary skill in the art without creative work are within the scope of the present disclosure.

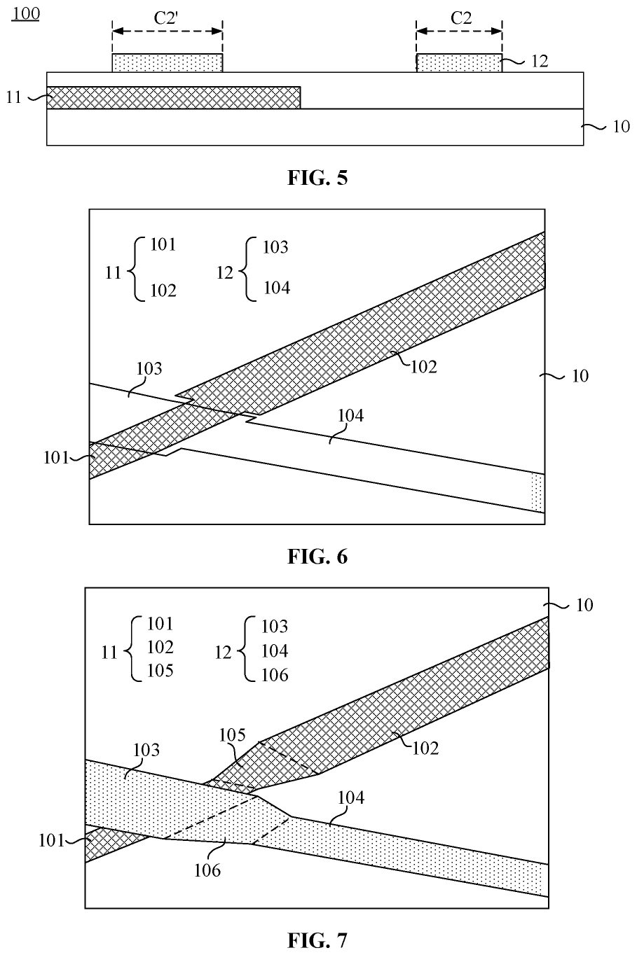

FIG. 4 is a partial enlarged view of a display panel according to an embodiment of the present disclosure. FIG. 5 is a partial section view taken along BB′ of the display panel of FIG. 4. Referring to FIG. 4 and FIG. 5, the display panel includes an array substrate 100. The array substrate 100 includes a base substrate 10 and first wires 11 and second wires 12 located on one side of the base substrate 10. A film layer where the first wires 11 are located is located between the base substrate 10 and a film layer where the second wires 12 are located. The orthographic projections of the first wires 11 on a plane where the base substrate 10 is located intersect the orthographic projections of the second wires 12 on the plane where the base substrate 10 is located. Wire widths C1′ of the first wires 11 at the intersections where the orthographic projections of the first wires 11 on the plane where the base substrate 10 is located intersect the orthographic projections of the second wires 12 on the plane where the base substrate 10 is located are smaller than at least part of wire widths C1 of the first wires 11 at positions other than the intersections. Wire widths C2′ of the second wires 12 at the intersections where the orthographic projections of the first wires 11 on the plane where the base substrate 10 is located intersect the orthographic projections of the second wires 12 on the plane where the base substrate 10 is located are greater than at least part of wire widths C2 of the second wires 12 at positions other than the intersections.

First, the wires described in this embodiment may be straight lines or curves. The wire width of the wire at any position indicates the width of the wire at the position in a direction perpendicular to a wire extension direction. It is to be understood that the wire width of the wire may be a fixed value, that is, the wire widths of wires at different positions are the same, or may be unfixed values, that is, the wire widths of wires at different positions may be different. In this embodiment, projection intersecting refers to the intersecting generated after the wires are orthographically projected on the plane where the base substrate is located. The positions of the projection intersections indicate regions where the projections of the first wires 11 intersect the projections of the second wires 12, and the positions other than the intersections indicate regions where the projections of the first wires 11 do not intersect the projections of the second wires 12.

For the scheme of decreasing the wire widths of the first wires 11 located in the lower layer at the positions of the projection intersections, the wire widths of the first wires 11 at the positions of the projection intersections in this embodiment of the present disclosure, as shown in FIG. 4, may be disposed to vary in a cliff-like manner compared with wire widths at other positions including adjacent positions, that is, only the wire widths of the first wires 11 at the intersections are correspondingly decreased. Of course, the first wires may be designed to have the smallest wire widths at the intersections, and to gradually increase the wire widths at other positions or to maintain relatively small wire widths for a certain length and then gradually increase. In other words, the object of this embodiment of the present disclosure is to design the wire widths of the first wires 11 at the intersections being smaller than an original design value, and the wire widths at other positions may be designed as required, so that in an actual display panel product, the wire widths of the first wires 11 at the intersections can be smaller than the wire widths of the first wires 11 at some other positions. Similarly, for the scheme of increasing the wire widths of the second wires 12 located in the upper layer at the intersections, in this embodiment of the present disclosure, the wire widths of the second wires 12 at the intersections are greater than an original design value, and the wire widths at other positions can be designed as required, so in an actual display panel product, the wire widths of the second wires 12 at the intersections can be greater than the wire widths at some other positions.

In this embodiment of the present disclosure, the array substrate includes the base substrate and the first wires and second wires located on one side of the base substrate. The film layer where the first wires are located is located between the base substrate and the film layer where the second wires are located. The orthographic projections of the first wires on a plane where the base substrate is located intersect the orthographic projections of the second wires on the plane where the base substrate is located. The wire widths of the first wires at intersections where the orthographic projections of the first wires on the plane where the base substrate is located intersect the orthographic projections of the second wires on the plane where the base substrate is located are smaller than at least part of wire widths of the first wires at positions other than the intersections, and/or the wire widths of the second wires at intersections where the orthographic projections of the first wires on the plane where the base substrate is located intersect the orthographic projections of the second wires on the plane where the base substrate is located are greater than at least part of wire widths of the second wires at positions other than the intersections. The embodiments of the present disclosure solve the wire breakage issue caused by a relatively narrow wire width due to overexposure at an intersection between projections of wires in an existing display panel. By increasing wire widths at wire intersections in the upper layer or decreasing wire widths at wire intersections in the lower layer, the overexposure at the intersections can be compensated or exposure amount at the intersections can be reduced, thereby preventing the exposure issue from causing the wire widths to be too small to cause the wire breakage, and effectively ensuring the wire quality, so that the display panel can work normally. Meanwhile, the embodiments of the present disclosure can wire in the bezel region of the display panel with a relatively small wire width under the premise of ensuring the wire quality, so that the bezel area can be reduced, the design of a narrow bezel can be facilitated in the display panel, and the product competitiveness can be improved.

It is to be noted that in the above-described display panel as shown in FIG. 4, the wire widths of the first wires 11 and the wire widths of the second wires 12 at the intersections are designed at the same time, and those skilled in the art may choose to design that only the wire widths of the first wires at the intersections are smaller than at least part of wire widths of the first wires at positions other than the intersections, or only the wire widths of the second wires at the intersections are greater than at least part of wire widths of the second wires at positions other than the intersections. The embodiments of the present disclosure are not limited to these.

FIG. 6 is a partial enlarged view of another display panel according to an embodiment of the present disclosure. Referring to FIG. 6, in an embodiment, one first wire 11 includes a first subwire 101 and a second subwire 102, and one second wire 12 includes a third subwire 103 and a fourth subwire 104. The orthographic projection of the first subwire 101 on the plane where the base substrate 10 is located intersects the orthographic projection of the third subwire 103 on the plane where the base substrate 10 is located. The wire width of the first subwire 101 is smaller than the wire width of the second subwire 102, and the wire width of the third subwire 103 is greater than the wire width of the fourth subwire 104.

The first subwire 101, the second subwire 102, the third subwire 103, and the fourth subwire 104 may each be a segment of wire in which the wire width remains unchanged as shown in FIG. 6, or may be a segment of wire in which the wire width changes. In this embodiment, one first wire 11 includes a first subwire 101 and a second subwire 102, and one second wire 12 includes a third subwire 103 and a fourth subwire 104, representing that the first wire 11 and the second wire 12 are each divided into two segments of wires that have obvious difference in wire width. The projection intersecting of the first wire 11 and the second wire 12 is actually the projection intersecting of some two segments of the wires divided according to the wire width. As shown in FIG. 6, the projection of the first subwire 101 intersects the projection of the third subwire 103. In this case, the first subwire 101 located in the lower layer may influence the exposure amount of the third subwire 103 during the manufacturing process. Therefore, it is to be understood that in this embodiment, the wire width of the first subwire 101 being disposed to be smaller than the wire width of the second subwire 102 and the wire width of the third subwire 103 being disposed to be greater than the wire width of the fourth subwire 104 are substantially to design the wire width of the first subwire 101 to be smaller than an original design wire width value of the first wire 11 at this position and the wire width of the third subwire 103 to be greater than the original design wire width value at this position, thereby weakening the influence of wire retroreflection on exposure and ensuring the wire quality.

Similarly, in this embodiment, a partial wire width design for the first wire 11 and the second wire 12 is illustrated at the same time. In this embodiment, only the wire width of the first subwire 101 may be disposed to be smaller than the wire width of the second subwire 102, or only the wire width of the third subwire 103 may be disposed to be greater than the wire width of the fourth subwire 104. Repetition is not made here.

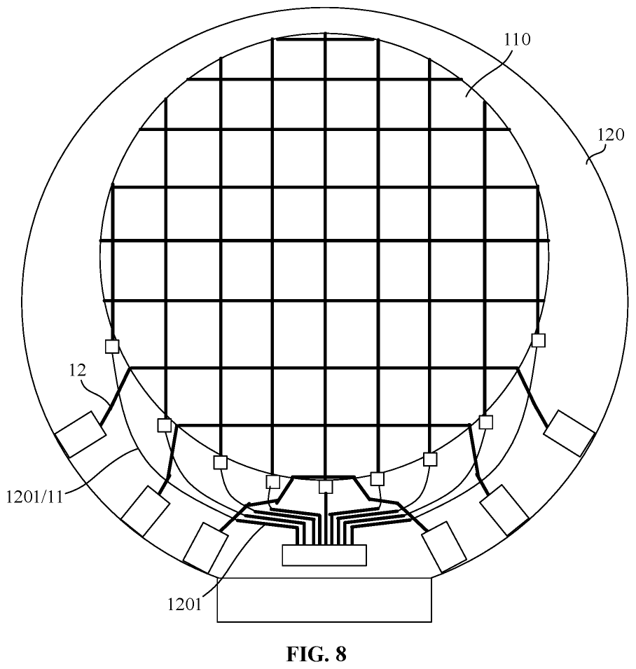

As shown in FIG. 6, the first wire 11 and the second wire 12 are each divided into two segments of wires having inconsistent wire widths, and wire widths of the two segments of wires vary in a cliff-like manner. Considering the beauty and practicality of a wire shape, this embodiment of the present disclosure further provides another display panel. FIG. 7 is a partial enlarged view of another display panel according to an embodiment of the present disclosure. Referring to FIG. 7, in this embodiment, one first wire 11 further includes a fifth subwire 105. A first end of the fifth subwire 105 is connected to the first subwire 101, and a second end of the fifth subwire 105 is connected to the second subwire 102. The wire width of the first end of the fifth subwire 105 is equal to the wire width of the first subwire 101, the wire width of the second end of the fifth subwire 105 is equal to the wire width of the second subwire 102, and the wire width of the fifth subwire 105 gradually increases from the first end of the fifth subwire 105 to the second end of the fifth subwire 105. One second wire 12 further includes a sixth subwire 106. A first end of the sixth subwire 106 is connected to the third subwire 103, and a second end of the sixth subwire 106 is connected to the fourth subwire 104. The wire width of the first end of the sixth subwire 106 is equal to the wire width of the third subwire 103, the wire width of the second end of the sixth subwire 106 is equal to the wire width of the fourth subwire 104, and the wire width of the sixth subwire 106 gradually decreases from the first end of the sixth subwire 106 to the second end of the sixth subwire 106.

The fifth subwire 105 is substantially a segment of wire of the first wire 11 responsible for connecting the first subwire 101 and the second subwire 102, and the sixth subwire 106 is substantially a segment of wire of the second wire 12 responsible for connecting the third subwire 103 and the fourth subwire 104. In this embodiment, disposing the fifth subwire 105 and the sixth subwire 106 indicates that when the wire width is designed for the first wire 11 and the second wire 12, the wire width can be designed according to a gradual change.

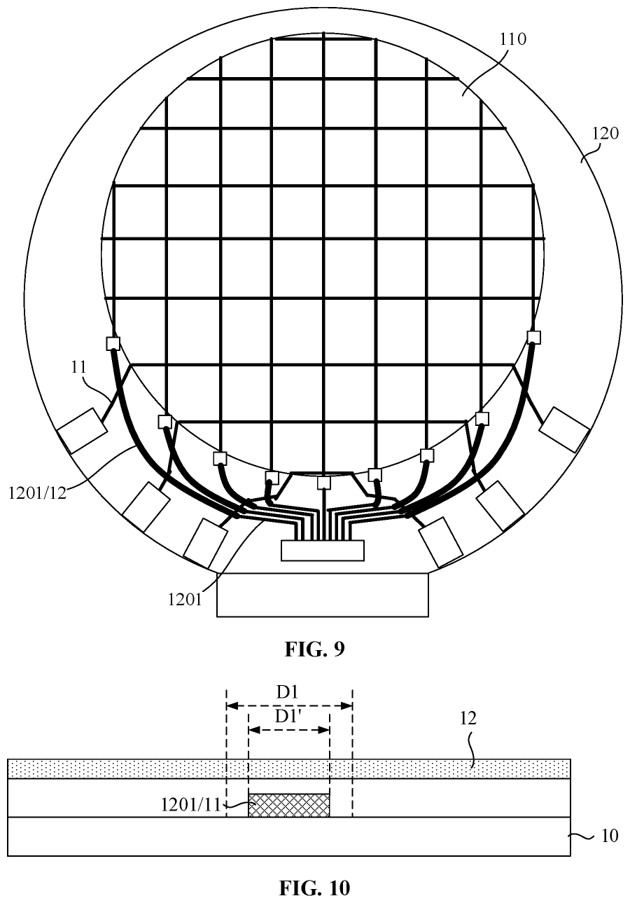

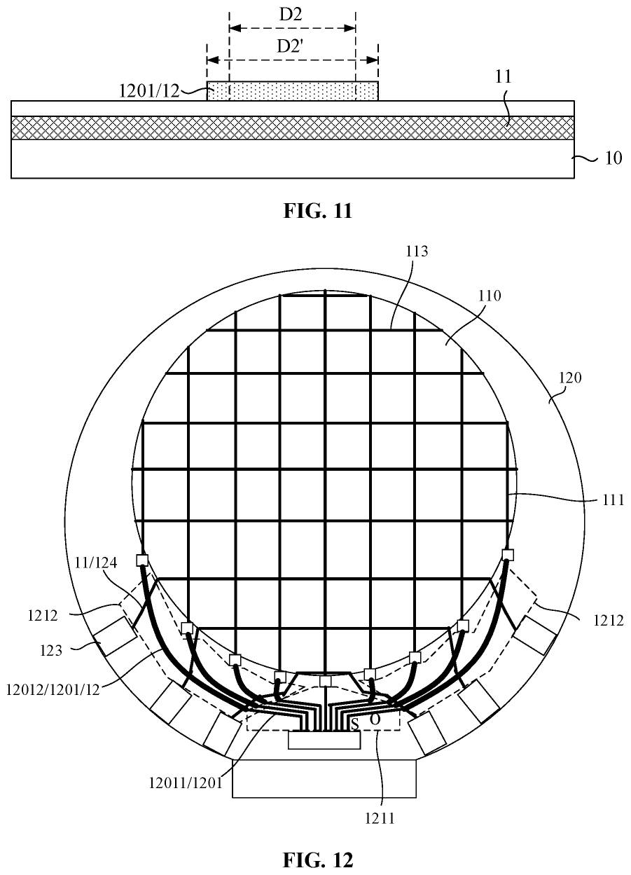

It is to be noted that the first wires and the second wires in this embodiment of the present disclosure may not be limited in a display region or a non-display region, or be limited to any two types of signal wires in the display panel. Two necessary conditions of the first wires and the second wires to be met are projection intersecting and manufactured by using a photolithography exposure technique. The following describes an application scenario in which the first wires and the second wires are signal wires in the non-display region of the display panel. FIG. 8 and FIG. 9 are structure diagrams of another two display panels according to an embodiment of the present disclosure. FIG. 10 is a section view taken along the direction perpendicular to the extension direction of fan-out wires of the display panel of FIG. 8. FIG. 11 is a section view taken along the direction perpendicular to the extension direction of fan-out wires of the display panel of FIG. 9. Referring to FIGS. 8 to 11, first, the display panel includes a display region 110 and a non-display region 120 surrounding the display region 110, and the first wires 11 and the second wires 12 are all located in the non-display region 120. The non-display region 120 includes a fan-out region. The fan-out region includes a plurality of fan-out wires 1201. At least part of the plurality of fan-out wires 1201 include the first wires 11 (as shown in FIG. 8 and FIG. 10) or the second wires 12 (as shown in FIG. 9 and FIG. 11).

The plurality of fan-out wires 1201 in the fan-out region may be understood as data signal lines in the non-display region 120 of the display panel, and may of course be touch signal lines in the non-display region 120 of a touch display panel. In other words, the plurality of fan-out wires 1201 are responsible for providing data signals to data signal lines in the display region 110 of the display panel, or for providing touch signals to touch signal lines in the display region 110 of the touch display panel. In this embodiment of the present disclosure, when it is considered that the projection of the fan-out region disposed in the non-display region 120 of the display panel intersects the projections of other wires such as scan signal lines, and the projections of the plurality of fan-out wires 1201 intersect the projections of other wires in an upper layer or a lower layer, the overexposure inevitably appears when manufacturing the fan-out wires or other projection-intersected wires. The following describes different cases of fan-out wires in the upper layer or the lower layer under a projection intersecting scenario.

Referring to FIG. 8 and FIG. 10, in response to the plurality of fan-out wires 1201 including the first wires 11, wire widths D1′ of the plurality of fan-out wires 1201 at the intersections are smaller than at least part of wire widths D1 of the plurality of fan-out wires 1201 at the positions other than the intersections. Referring to FIG. 9 and FIG. 11, in response to the plurality of fan-out wires 1201 including the second wires 12, wire widths D2′ of the plurality of fan-out wires 1201 at the intersections are greater than at least part of wire widths D2 of the plurality of fan-out wires 1201 at the positions other than the intersections.

Referring to FIG. 8 and FIG. 10, the plurality of fan-out wires 1201 includes the first wires 11, that may indicate that projections of part of the plurality of fan-out wires 1201 intersect projections of other wires, and that the plurality of fan-out wires 1201 belong to the lower film layer under the projection intersecting scenario, which can influence the exposure of wires in an upper film layer during the manufacturing process, resulting in a decrease in wire widths of the wires in the upper film layer. Meanwhile, considering that fan-out wires may be multi-segment head-to-tail connected subwires (not shown), different segments of subwires are located in different film layers. Therefore, the plurality of fan-out wires 1201 including the first wires 11 may also indicate that the projection of a segment of subwire in one of the plurality of fan-out wires 1201 intersects the projections of other wires, and that the segment of subwire in the one of the plurality of fan-out wires 1201 belongs to the lower film layer under the projection intersection scenario, which likewise influences exposure of the wires in the upper film layer during the manufacturing process, resulting in a decrease in wire widths of the wires in the upper film layer. Here, the fan-out wires or the subwires projection intersecting other wires in the upper layer are represented by the concept of the first wires, based on which the fan-out wires or the subwires may be designed for the wire widths according to the concept of the first wires. That is, the wire widths at the projection intersections of the fan-out wires and other wires are decreased compared with the original design value and are smaller than at least part of wire widths of the fan-out wires at the positions other than the intersections.

Similarly, referring to FIG. 9 and FIG. 11, under another projection intersecting scenario, the projections of the fan-out wires 1201 which may as the wires in the upper layer intersect the projections of other wires in the lower layer. In this case, the plurality of fan-out wires 1201 include the second wires 12 indicating that the projections of the fan-out wires or the projection of a segment of subwire of the fan-out wires intersects projections of other wires in the lower layer, so the exposure amount of the fan-out wires is influenced by the wires in the lower layer during the manufacturing process, resulting in a decrease of the wire widths. Here, the fan-out wires or the subwires projection intersecting other wires in the lower layer are represented by the concept of the second wires. Based on this, the fan-out wires or the subwires may be designed for the wire widths according to the concept of the second wires. That is, the wire widths at the projection intersections of the fan-out wires and other wires are increased compared with the original design value and are greater than at least part of wire widths of the fan-out wires at the positions other than the intersections.

FIG. 12 is a structure diagram of another display panel according to an embodiment of the present disclosure. Referring to FIG. 12, a fan-out region includes a first fan-out region 1211 and a second fan-out region 1212. The wiring density of the plurality of fan-out wires 1201 in the first fan-out region 1211 is greater than the wiring density of the plurality of fan-out wires 1201 in the second fan-out region 1212. In this embodiment, the plurality of fan-out wires 1201 include the second wires 12. The projections of the second wires 12 at least partially intersect the projection of the second fan-out region 1212, and the projections of the first wires 11 at least partially intersect the projections of the second wires 12 in the second fan-out region 1212.

The projections of the second wires 12 at least partially intersect the projection of the second fan-out region 1212, indicating that the second wires 12 pass through the second fan-out region 1212, and that the partial structure of the second wires 12 is located in the second fan-out region 1212. The projections of the first wires 11 at least partially intersect the projections of the second wires 12 in the second fan-out region 1212, indicating that the projections of the first wires 11 intersect the projection of the partial structure of the second wires 12 located in the second fan-out region 1212, and that the first wires 11 are located in the lower layer of the second wires 12 in this case. Substantially, this embodiment is that the projections of part of the plurality of fan-out wires 1201 which may use as the second wires 12 in the second fan-out region 1212 intersect the projections of the first wires 11, based on this, the wire widths of the plurality of fan-out wires 1201 in the second fan-out region 1212 located in the upper layer may be selected to be designed in this embodiment, that is, at least the wire widths at the projection intersections of the plurality of fan-out wires 1201 in the second fan-out region 1212 and the first wires 11 are increased. In this embodiment, the first fan-out region 1211 may include first fan-out wires 12011, and the second fan-out region 1212 may include second fan-out wires 12012. The wire widths of the second fan-out wires 12012 are greater than the wire widths of the first fan-out wires 12011. In this case, the wire widths of the second fan-out wires 12012 in the upper layer which intersect the first wires 11 are increased compared with the original design value, and the narrow wire width caused by the overexposure can be compensated to some extent, thereby ensuring the quality of the second fan-out wires 12012.

As the above embodiment, substantially, the wire widths of the second fan-out wires 12012 are designed based on the second fan-out wires 12012 in the second fan-out region 1212 as the second wires 12 intersecting other wires located in the lower layer by projection. Considering the complexity of wires in an actual array substrate, a reasonable wire width design may be performed for a scenario where the second fan-out wires are used as the first wires intersecting other wires located in the upper layer by projection. In an embodiment, the fan-out wires include the first wires. The projections of the first wires at least partially intersect the projection of the second fan-out region. The projections of the second wires at least partially intersect the projections of the first wires in the second fan-out region 1212.

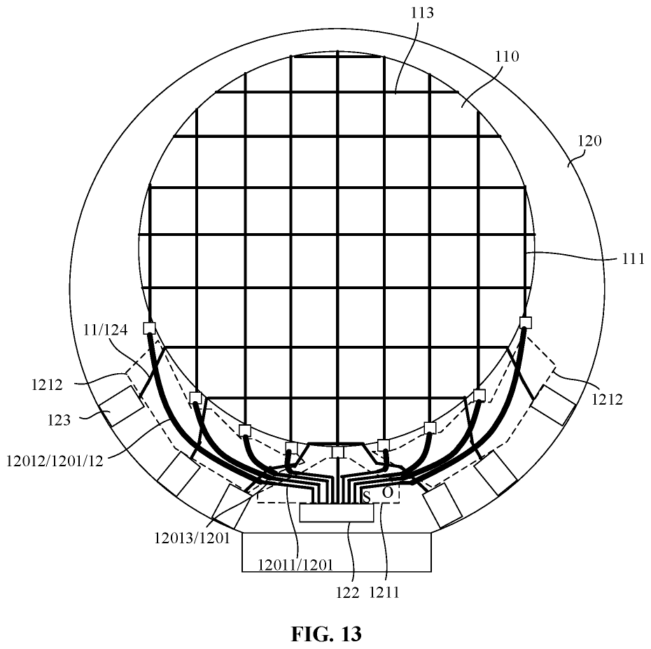

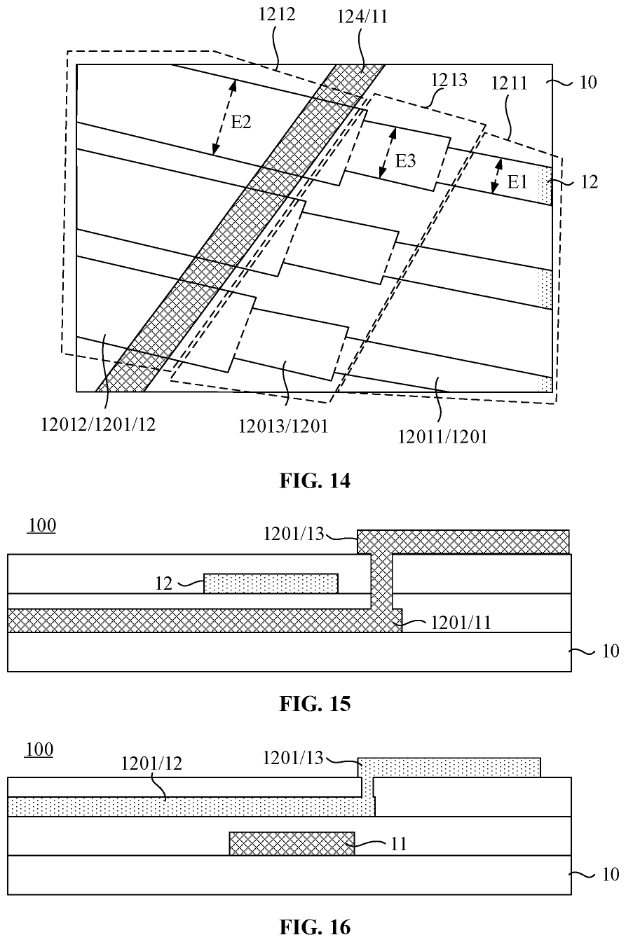

FIG. 13 is a structure diagram of another display panel according to an embodiment of the present disclosure. FIG. 14 is a partial enlarged view of the fan-out region shown in FIG. 13. On the basis of the display panel design shown in FIG. 12, referring to FIG. 13 and FIG. 14, in an embodiment, a fan-out region further includes a third fan-out region 1213, and the wiring density of the plurality of fan-out wires 1201 in the third fan-out region 1213 is between the wiring density of the plurality of fan-out wires 1201 in the first fan-out region 1211 and the wiring density of the plurality of fan-out wires 1201 in the second fan-out region 1212. Further, the first fan-out region 1211 includes the first fan-out wires 12011, the second fan-out region 1212 includes the second fan-out wires 12012, and the third fan-out region 1213 includes third fan-out wires 12013. One of at least part of the first fan-out wires 12011 is electrically connected to one of the second fan-out wires 12012 corresponding to the one of the at least part of the first fan-out wires 12011 through one of the third fan-out wires 12013 corresponding to the one of the at least part of the first fan-out wires 12011. Wire widths E3 of the third fan-out wires 12013 are greater than wire widths E1 of the first fan-out wires 12011 and smaller than or equal to wire widths E2 of the second fan-out wires 12012.

The third fan-out wires 12013 are responsible for transitioning the first fan-out wires 12011 and the second fan-out wires 12012 because the wire widths of the first fan-out wires 12011 and the second fan-out wires 12012 are inconsistent. One of the third fan-out wires 12013 may be a segment of subwire whose wire width is gradually changed, or may be a segment of subwire whose wire width is fixed as shown in FIG. 14. In other words, in the display panel according to this embodiment of the present disclosure, part of the plurality of fan-out wires 1201 according to different regions may be divided into only the first fan-out wires 12011 and the second fan-out wires 12012 connected to each other, or part of the plurality of fan-out wires 1201 may be divided into three segments of subwires according to different regions, that is, the first fan-out wires 12011, the third fan-out wires 12013 and the second fan-out wires 12012 sequentially connected head to tail. In this embodiment, the third fan-out wires are only responsible for connecting the second fan-out wires and the first fan-out wires, so the wire widths of the third fan-out wires should be between the wire widths of the first fan-out wires and the wire widths of the second fan-out wires. In this embodiment, exemplarily, since the projections of the second fan-out wires 12012 as the second wires 12 intersect the projections of other wires located in the lower layer, the wire widths of the second fan-out wires 12012 are disposed to be greater than the wire widths of the first fan-out wires 12011, so that the decrease in the wire widths due to the increase in the exposure amount caused by the retroreflection of wires in the lower layer can be compensated. Of course, the embodiment in which the third fan-out region and the third fan-out wires are disposed is also applicable to the scenario where the projections of the second fan-out wires as the first wires intersect the projections of other wires located in the upper layer, and the wire widths of the second fan-out wires are properly designed to compensate for the wire width variation of the wires in the upper layer caused by the projection intersecting, avoiding the wire breakage.

In the display panels shown in FIG. 12 and FIG. 13, the wire widths of the first fan-out wires 12011 may range from 1.5 μm to 4 μm, and the wire widths of the second fan-out wires 12012 may range from 2 μm to 8 μm. In this case, on the basis that the wire widths of the first fan-out wires 12011 are smaller than those of the second fan-out wires 12012, the wire widths of the first fan-out wires 12011 can be ensured at a relatively small level under the conditions allowed by the manufacturing technique, which is conducive to reducing the area of the fan-out region and achieving the design of a narrow bezel. Meanwhile, the wire widths of the second fan-out wires 12012 ranging from 2 μm to 8 μm are increased to some extent compared with those of the first fan-out wires 12011, so that the decrease in wire widths caused by the increase in the exposure amount can be compensated. On this basis, the wire widths of the first fan-out wires 12011 not less than 1.5 μm can avoid that the electrical impedance is too high due to the wire width being too small, and also prevent the un-accurate wire widths caused by the diffraction phenomenon due to the wire widths being too small during the manufacturing process, thereby meeting the current manufacturing technique requirements. Meanwhile, the wire widths of the first fan-out wires 12011 not more than 4 μm can reduce the spacing between centers of the first fan-out wires 12011, that is, the wiring density of the first fan-out region 1211 is increased, the area of the first fan-out region 1211 is more compact, and the arrangement of bonding pads in a bonding region is accommodated. The wire widths of the second fan-out wires 12012 not less than 2 μm can also ensure a relatively high electrical impedance and avoid the electrical impedance caused by wire widths. Moreover, the wire widths of the second fan-out wires 12012 not greater than 8 μm are also considered that the second fan-out region 1212 is located in the bezel region, in which the number of fan-out wires in the second fan-out region 1212 is equal to that in the first fan-out region 1211, but the area of the second fan-out region 1212 is only slightly larger than that of the first fan-out region 1211, so that the bezel area can be effectively reduced.

Further, the line spacing between any two adjacent first fan-out wires 12011 may be less than or equal to the line spacing between any two adjacent second fan-out wires 12012. As shown above (see FIG. 2), the greater the spacing between centers of two fan-out wires is, the greater the components of the two fan-out wires in the longitudinal direction are. The line spacing of the two first fan-out wires 12011 is disposed to be smaller than the line spacing of the two second fan-out wires 12012, essentially reducing the spacing between centers of the fan-out wires in the first fan-out region through the line spacing, so that in the longitudinal direction, the length of the fan-out wires in the first fan-out region can be reduced. In this case, the spacing between the fan-out wires in the first fan-out region is disposed to be smaller, which is conducive to shortening the lower bezel of the display panel in the longitudinal direction and achieving the design of a narrow bezel. In an embodiment, the spacing between any two adjacent first fan-out wires 12011 may be 4 μm to 7 μm, and the spacing between any two adjacent second fan-out wires 12012 may be 5 μm to 10 μm. Similarly, the above-disposed line spacing ranges of the first fan-out wires 12011 and the second fan-out wires 12012 can ensure the line spacings of the first fan-out wires 12011 and the second fan-out wires 12012 at a relatively small level under the conditions allowed by a manufacturing technique, which is conducive to reducing the area of the fan-out region and achieving the design of a narrow bezel. The line spacing of the first fan-out wires 12011 not less than 4 μm can provide an appropriate space between the fan-out wires and prevent the signals on the fan-out wires from being disturbed by adjacent wires. Moreover, the line spacing of the first fan-out wires 12011 not greater than 7 μm can effectively increase the wiring density of the first fan-out wires, avoid the area of the first fan-out region being too large, and accommodate the arrangement design of the bonding pads in the bonding region. On the basis of accommodating the relatively small area of the second fan-out region 1212, the line spacing of the second fan-out wires 12012 not less than 5 μm and not more than 10 μm appropriately increases the line spacing of the second fan-out wires 12012 compared with that of the first fan-out wires 12011, improves the wiring density, and effectively avoids the signal interference between wires.

With continued reference to FIG. 12 and FIG. 13, in this embodiment, the non-display region 120 includes a bonding region 122. The bonding region 122 includes a plurality of bonding pads (not shown). The display region 110 further includes a plurality of data signal lines 111 or a plurality of touch signal lines (not shown). One end of one of the plurality of fan-out wires 1201 is connected to one of the plurality of data signal lines 111 or one of the plurality of touch signal lines (not shown), and the other end of the one of the plurality of fan-out wires 1201 is connected to one of the plurality of bonding pads.

As shown in FIG. 12 and FIG. 13, in response to the plurality of fan-out wires 1201 including the second wires 12, one end of one of the second wires 12 is connected to the one of the plurality of data signal lines 111 or the one of the plurality of touch signal lines, and the other end of the one of the second wires 12 is connected to the one of the plurality of bonding pads. It is to be understood that the fan-out wires in this embodiment of the present disclosure may also intersect some wires in the upper layer by projection. In this case, the fan-out wires substantially include the first wires. One end of one of the first wires is connected to the one of the plurality of data signal lines or the one of the plurality of touch signal lines, and the other end of the one of the first wires is connected to the one of the plurality of bonding pads.

In an embodiment, one of the first fan-out wires 12011 may include a straight line portion S and an oblique line portion O. One end of the straight line portion S is electrically connected to a respective one of the plurality of bonding pads in one-to-one correspondence, the other end of the straight line portion S is electrically connected to one end of the oblique line portion O, and the other end of the oblique line portion O is electrically connected to one of the second fan-out wires 12012.

Further, the display panels shown in FIG. 12 and FIG. 13 are taken as examples. The second fan-out region 1212 includes the second fan-out wires 12012. In the direction from the display region 110 toward the non-display region 120, a plurality of the second fan-out wires 12012 may include a plurality of second fan-out wire groups. Each of the plurality of second fan-out wire groups may include at least one of the plurality of second fan-out wires 12012. In the plurality of second fan-out wire groups, a wire width of one second fan-out wire 12012 in one second fan-out wire group farther away from the display region 110 is wider.

The fan-out wires in the non-display region 120 extend in parallel along the boundary between the non-display region 120 and the display region 110. In other words, the fan-out wires are arranged sequentially from the display region 110 toward the non-display region 120.

In this embodiment, the plurality of second fan-out wires 12012 include the plurality of second fan-out wire groups, and each of the plurality of second fan-out wire groups includes at least one second fan-out wire 12012, and the essence is to divide the plurality of second fan-out wires 12012 into the plurality of second fan-out wire groups, and each second fan-out wire group may be provided with at least one second fan-out wire and have the same number or different numbers of second fan-out wires. In addition, the second fan-out wires 12012 in the second fan-out wire groups farther away from the display region 110 need to extend in the bezel region longer. In this embodiment, the longer the second fan-out wires 12012 are disposed, the wider the wire widths of the second fan-out wires 12012 are, which actually reduces the electrical impedance of the second fan-out wires 12012 and compensates the electrical impedance of the second fan-out wires of different lengths by using the wire width design. Therefore, the second fan-out wires of different lengths can be ensured to have relatively uniform electrical impedance, thereby avoiding the nonuniform display of pixel units in the display region caused by the excessive difference in the electrical impedance of different second fan-out wires.

In addition, it is to be noted that the fan-out wires in the fan-out region according to this embodiment of the present disclosure may be disposed in a certain fixed film layer, or the same fan-out wire may be disposed by a jumper from one film layer to another film layer for reasons of reduction in the electrical impedance, fan-out facilitation, and the like. Based on this, this embodiment of the present disclosure also gives detailed examples. FIG. 15 and FIG. 16 are two section views taken along the extension direction of fan-out wires of the display panel in

FIG. 12. Referring to FIG. 15 and FIG. 16, the array substrate 100 may further include third wires 13 located on one side of the base substrate 10. As shown in FIG. 15, the third wires 13 and the first wires 11 are located in different film layers of the array substrate 10, and at least part of the fan-out wires 1201 include the first wires 11 and the third wires 13 connected to each other. The other end of one of the first wires 11 is connected to one of the plurality of data signal lines or one of the plurality of touch signal lines (not shown), and the other end of one of the third wires 13 is connected to one of the plurality of bonding pads (not shown). Alternatively, as shown in FIG. 16, the third wires 13 and the second wires 12 are located in different film layers of the array substrate 10. At least part of the fan-out wires 1201 include the second wires 12 and the third wires 13 connected to each other. The other end of one of the second wires 12 is connected to the one of the plurality of data signal lines or the one of the plurality of touch signal lines (not shown), and the other end of one of the third wires 13 is connected to the one of the plurality of bonding pads (not shown).

In contrast to the fan-out wires shown in FIG. 15 and FIG. 16, one of the plurality of fan-out wires 1201 in this embodiment of the present disclosure may include two segments of subwires located in two film layers and connected to each other. Because of the presence of the two segments of subwires, the projections of the fan-out wires 1201 may intersect the projections of other wires either in the upper layer or in the lower layer in the array substrate.

Part of the plurality of fan-out wires 1201 including the first wires 11 and the third wires 13 is taken as an example, which indicates that a segment of subwire in one of the plurality of fan-out wires 1201 may be used as the first wire 11 to intersect other wires in the upper layer by projection. Similarly, for the case in FIG. 16 where part of the plurality of fan-out wires 1201 include the second wires 12 and the third wires 13, it indicates that a segment of wire in one of the plurality of fan-out wire 1201 may be used as the second wire 12 to intersect other wires in the lower layer by projection. Based on this, in this embodiment of the present disclosure, the wire width of a segment of subwire of the fan-out wires which intersects wires in other layers is designed, so that the wire width variation caused by the projection intersecting can be compensated. Repetition is not made here.

It is to be noted that the above are only two examples of possible situations. In FIG. 15, the other end of one of the first wires 11 is connected to one of the plurality of data signal lines or one of the plurality of touch signal lines, and the other end of one of the third wires 13 is connected to one of the plurality of bonding pads, which may be converted into that the other end of one of the third wires 13 is connected to one of the plurality of data signal lines or one of the plurality of touch signal lines and the other end of one of the first wires 11 is connected to one of the plurality of bonding pads. Similarly, in FIG. 16, the other end of one of the second wires 12 is connected to one of the plurality of data signal lines or one of the plurality of touch signal lines, and the other end of one of the third wires 13 is connected to one of the plurality of bonding pads, which may be converted into that the other end of one of the third wires 13 is connected to one of the plurality of data signal lines or one of the plurality of touch signal lines and the other end of one of the second wires 12 is connected to one of the plurality of bonding pads.

In addition, it is to be noted that the specific jumper mode of the fan-out wires is not excessively limited in this embodiment of the present disclosure. It is to be understood that the present disclosure is applicable to various jumper designs provided for various reasons, such as the case in which the same fan-out wire performs jumper between different film layers multiple times, or the case in which different fan-out wires adopt jumpers of different modes.

The fan-out wire film layer design according to this embodiment of the present disclosure is described and illustrated below with reference to an actual array substrate film layer structure. In an embodiment, the array substrate may further include a first metal layer and a second metal layer stacked on one side of the base substrate, and at least part of the plurality of fan-out wires are located in the second metal layer.

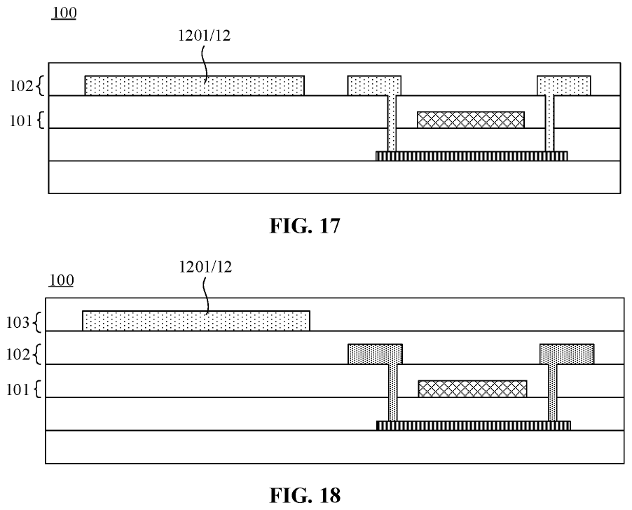

FIG. 17 is a section view of another display panel according to an embodiment of the present disclosure. Referring to FIG. 17, the array substrate 100 further includes a first metal layer 101 and a second metal layer 102 stacked on one side of the base substrate 10, and at least part of the plurality of fan-out wires 1201 are located in the second metal layer 102.

Those skilled in the art can understand that the array substrate in the display panel includes pixel driver circuits, and each pixel driver circuit includes a transistor and a capacitor. Generally, the metal layer in which the gate of the transistor is located is the first metal layer 101, the metal layer in which the source and drain of the transistor are located is the second metal layer 102, and the inter insulating layer is disposed between the first metal layer 101 and the second metal layer 102 for isolation. In addition, scan signal lines are disposed in the array substrate and electrically connected to the gates of transistors, and the scan signal lines are disposed in the first metal layer 101. Meanwhile, data signal lines are electrically connected to the sources and drains of the transistors, and the data signal lines are disposed in the second metal layer 102. In this embodiment, the plurality of fan-out wires 1201 may select the jumper mode with only part of subwire segments formed in the second metal layer 102 so as to be directly connected to the data signal lines, and other parts of subwire segments may jump into the first metal layer 101 or other metal layers. Alternatively, the plurality of fan-out wires 1201 may be formed entirely in the second metal layer 102. The plurality of fan-out wires 1201 in this embodiment are substantially responsible for transmitting data signals.

In another embodiment, the array substrate may further include a first metal layer, a second metal layer, and a third metal layer stacked on one side of the base substrate, and at least part of the fan-out wires are located in the second metal layer or the third metal layer. FIG. 18 is a section view of another display panel according to an embodiment of the present disclosure. Referring to FIG. 18, the array substrate 100 further includes a first metal layer 101, a second metal layer 102, and a third metal layer 103 stacked on one side of the base substrate 10, and at least part of the plurality of fan-out wires 1201 are located in the third metal layer 103.

As described above, the first metal layer 101 and the second metal layer 102 are generally used to form the gates and the sources and drains of the transistors in the pixel driver circuits, respectively. The display panel according to this embodiment further includes the third metal layer 103, which may be used to form a touch functional layer on the array substrate, that is, touch electrodes and touch signal lines are formed by using the third metal layer 103. In this embodiment, part of subwire segments of the plurality of fan-out wires 1201 may be disposed in the third metal layer 103 to be directly electrically connected to the touch signal lines in the third metal layer 103. In this case, the plurality of fan-out wires 1201 are substantially responsible for transmitting touch signals. Of course, in other embodiments of the present disclosure, the third metal layer 103 may be disposed in the array substrate as the jumper layer of wires in the lower metal layer, that is, part of subwire segments of the plurality of fan-out wires 1201 may be jumped to the third metal layer 103. In this case, part of wires of the plurality of fan-out wires 1201 are located in the second metal layer 102, and the plurality of fan-out wires 1201 are substantially responsible for transmitting data signals.

As in the above embodiments, exemplary schemes are provided for the possible wiring projection intersecting of the fan-out wires in the fan-out region of the display panel. The present disclosure also considers that scan signal lines in the non-display region may also have the wire projection intersecting, and therefore, the following describes and illustrates the scheme corresponding to the wire projection intersecting of the scan signal lines.

In other embodiments of the present disclosure, the non-display region of the display panel further includes a plurality of shift registers and a plurality of scan signal lines. The display region includes a plurality of gate signal lines, one end of one of the plurality of scan signal lines is connected to one of the plurality of shift registers, and the other end of the one of the plurality of scan signal lines is connected to one of the plurality of gate signal lines. At least part of the plurality of scan signal lines include the first wires or the second wires.

Similarly to the fan-out wires described above, the plurality of scan signal lines may have part of subwire segments intersecting the wires in the upper layer or the wires in the lower layer by projection, resulting in variations in wire widths of other wires or variations generated by actual manufacture of the plurality of scan signal lines themselves due to the issue of exposure amount. That is, the part of wires of the plurality of scan signal lines may be used as the first wires or the second wires, and then wire widths of the plurality of scan signal lines may be designed accordingly. In an embodiment, in response to the plurality of scan signal lines including the first wires, wire widths of the plurality of scan signal lines at the intersections are smaller than at least part of wire widths of the plurality of scan signal lines at the positions other than the intersections. In response to the plurality of scan signal lines including the second wires, wire widths of the plurality of scan signal lines at the intersections are greater than at least part of wire widths of the plurality of scan signal lines at the positions other than the intersections.

Continue to take the display panels shown in FIG. 12 and FIG. 13 as examples. The non-display region 120 further includes a plurality of shift registers 123 and a plurality of scan signal lines 124. The display region 110 includes a plurality of gate signal lines 113. One end of one of the plurality of scan signal lines 124 is connected to one of the plurality of shift registers 123, and the other end of the one of the plurality of scan signal lines 124 is connected to one of the plurality of gate signal lines 113. At least part of the plurality of scan signal lines 124 include the first wires 11.

In this case, the projections of the plurality of scan signal lines 124 substantially intersect the projections of the plurality of fan-out wires 1201 in the upper layer, so that the wire widths of the plurality of fan-out wires 1201 actually formed change when manufacturing due to the exposure amount. The wire widths of the plurality of scan signal lines 124 disposed at the intersections are smaller than at least part of the wire widths of the plurality of scan signal wires 124 at the positions other than the intersections, which is substantially to reduce the wire width design values of the plurality of scan signal lines 124 at the intersections to appropriately reduce the retroreflection in the exposure process when manufacturing the plurality of fan-out wires 1201, avoid an excessive reduction in the wire widths of the plurality of fan-out wires 1201, and prevent the breakage of the plurality of fan-out wires 1201.

With continued reference to FIG. 12 and FIG. 13, further, in an embodiment of the present disclosure, in the extension direction of the plurality of gate signal lines 113, the plurality of scan signal lines 124 include a plurality of scan signal line groups, each of the plurality of scan signal line groups may include at least one of the plurality of scan signal lines 124. In the plurality of scan signal line groups, a scan signal line 124 electrically connected to a longer gate signal line 113 has a greater wire width.

Those skilled in the art can be understood that the plurality of scan signal lines 124 in the non-display region and the plurality of gate signal lines 113 in the display region, which are electrically connected to each other, are substantially responsible for sequentially transmitting the same scan signal to pixel units in the display region 110. The plurality of scan signal lines 124 and the plurality of gate signal lines 113 have certain electrical impedance, which can influence scan signals actually reaching the pixel units. Further, the electrical impedance of the plurality of scan signal lines 124 and the electrical impedance of the plurality of gate signal lines 113 also depend on the length of the plurality of scan signal lines 124 and the length of the plurality of gate signal lines 113 to some extent. That is, the longer the line length is, the higher the electrical impedance is, and the more severe the pixel units are influenced. In this embodiment, on the basis of the above wire width design of the plurality of scan signal lines 124, the plurality of scan signal lines 124 are divided into the plurality of scan signal line groups based on line lengths of the plurality of gate signal lines in the display region. The number of scan signal lines 124 in each scan signal line group may be the same or different, and at least one scan signal line 124 is included. Further, wire widths of different scan signal line groups are designed according to lengths of gate signal lines 113 corresponding to the scan signal line groups. That is, in the plurality of scan signal line groups, the longer a gate signal line 113 is, the wider the wire width of the scan signal line 124 electrically connected to the gate signal line 113 is. Therefore, the relatively high electrical impedance generated by a relatively long gate signal line 113 can be compensated, and the electrical impedance on each gate signal line 113 is maintained balanced, so that scan signals transmitted in the plurality of gate signal lines 113 are not different due to the electrical impedance, thus ensuring the uniform display of the display region and improving the display effect.

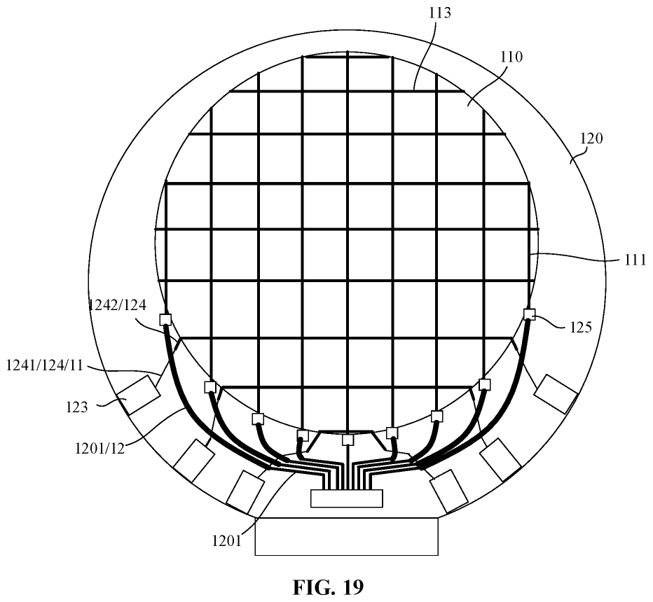

FIG. 19 is a structure diagram of another display panel according to an embodiment of the present disclosure. Referring to FIG. 19, each of at least part of the plurality of scan signal lines 124 includes a first scan signal line 1241 and a second scan signal line 1242. The first scan signal line 1241 is electrically connected to the second scan signal line 1242 in one-to-one correspondence. One end of the first scan signal line 1241 farther away from the second scan signal line 1242 is connected to the one of the plurality of shift registers 123, and one end of the second scan signal line 1242 farther away from the first scan signal line 1241 is connected to the one of the plurality of gate signal lines 113. First scan signal lines 1241 of the at least part scan signal lines 124 include the first wires 11. The plurality of fan-out wires 1201 include the second wires 12. The orthographic projections of second scan signal lines 1242 on the plane where the base substrate 10 is located do not intersect the orthographic projections of the plurality of fan-out wires 1201 on the plane where the base substrate 10 is located. The wire widths of the first scan signal line 1241 are smaller than a wire width of at least part of the second scan signal line 1242.

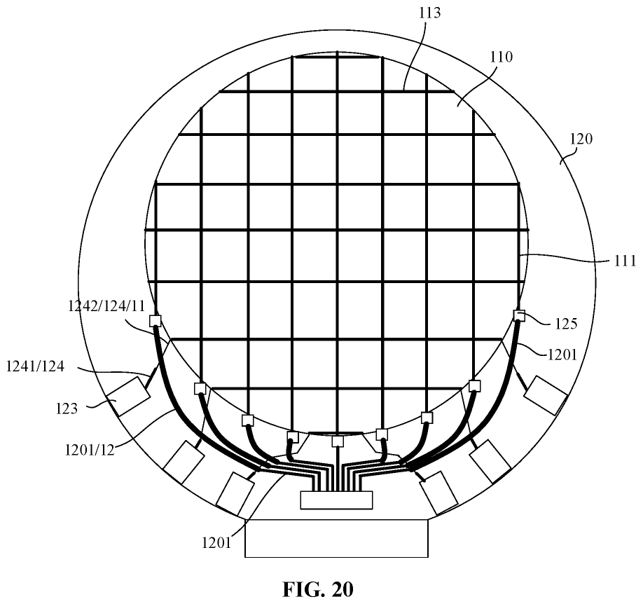

FIG. 20 is a structure diagram of another display panel according to an embodiment of the present disclosure. Referring to FIG. 20, in another embodiment of the present disclosure, each of at least part of the plurality of scan signal lines 124 includes a first scan signal line 1241 and a second scan signal line 1242. The first scan signal line 1241 may be electrically connected to the second scan signal line 1242 in one-to-one correspondence. One end of the first scan signal line 1241 farther away from the second scan signal line 1242 is connected to the one of the plurality of shift registers 123, and one end of the second scan signal line 1242 farther away from the first scan signal line 1241 is connected to the one of the plurality of gate signal lines 113. The second scan signal lines 1242 of the at least part scan signal lines 124 include the first wires 11. The plurality of fan-out wires 1201 include the second wires 12. The orthographic projections of the first scan signal lines 1241 on the plane where the base substrate 10 is located do not intersect the orthographic projections of the plurality of fan-out wires 1201 on the plane where the base substrate 10 is located. The wire widths of the second scan signal line 1242 are smaller than a wire width of at least part of the first scan signal line 1241.

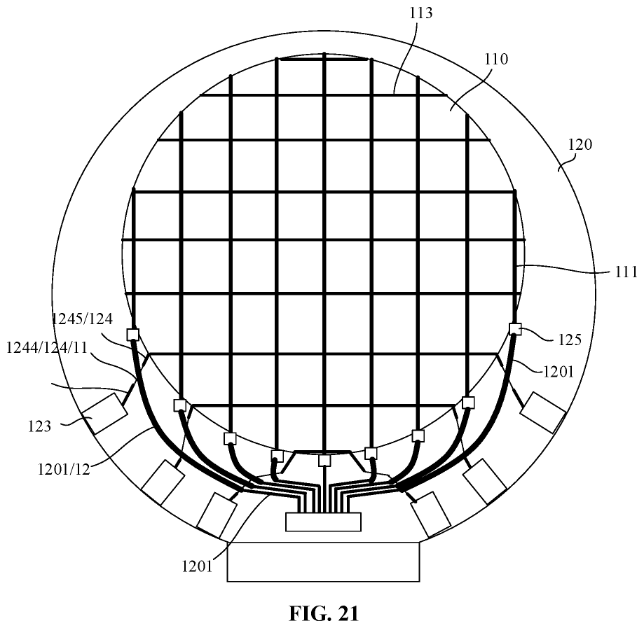

FIG. 21 is a structure diagram of another display panel according to an embodiment of the present disclosure. Referring to FIG. 21, in another embodiment of the present disclosure, one of the plurality of scan signal lines 124 includes a third scan signal line 1243, a fourth scan signal line 1244, and a fifth scan signal line 1245. The third scan signal line 1243, the fourth scan signal line 1244, and the fifth scan signal line 1245 are sequentially electrically connected head to tail in one-to-one correspondence. One end of the third scan signal line 1243 farther away from the fourth scan signal line 1244 is connected to the one of the plurality of shift registers 123, and one end of the fifth scan signal line 1245 farther away from the fourth scan signal line 1244 is connected to the one of the plurality of gate signal lines 113. Fourth scan signal lines 1244 of the plurality of scan signal lines 124 include the first wires 11. The plurality of fan-out wires 1201 include the second wires 12. The orthographic projections of third scan signal lines 1243 of the plurality of scan signal lines 124 on the plane where the base substrate 10 is located and the orthographic projections of fifth scan signal lines 1245 of the plurality of scan signal lines 124 on the plane where the base substrate 10 is located do not intersect the orthographic projections of the plurality of fan-out wires 1201 on the plane where the base substrate 10 is located. The wire widths of the fourth scan signal lines 1244 are smaller than at least part of wire widths of the third scan signal lines 1243 and at least part of wire widths of the fifth scan signal lines 1245.

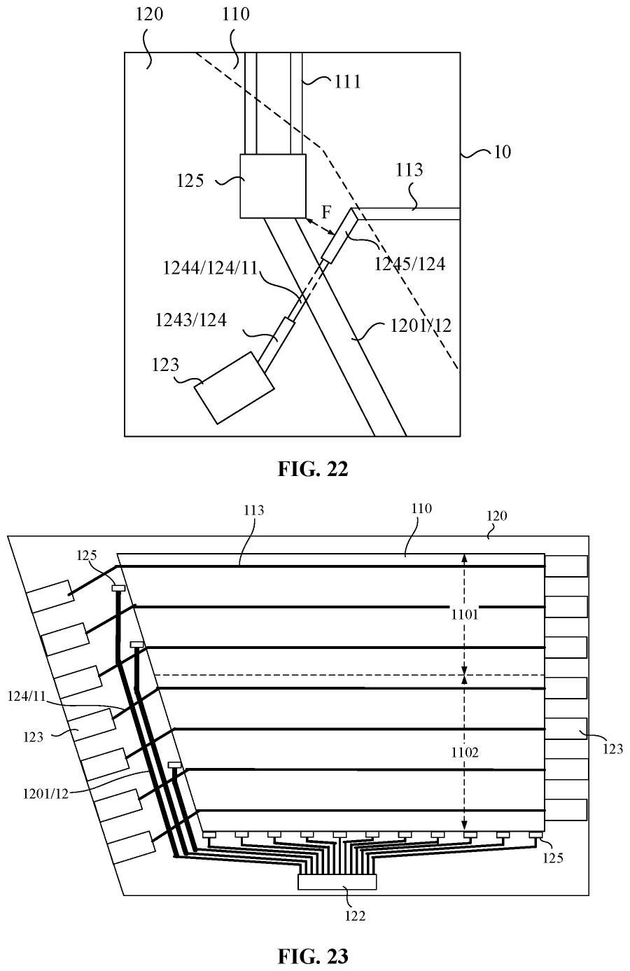

FIG. 22 is a partial enlarged view of a bezel region of the display panel of FIG. 21. Referring to FIG. 21 and FIG. 22, the non-display region 120 further includes a plurality of multiplexers 125. The output end of one of the plurality of multiplexers 125 is electrically connected to at least two of the plurality of data signal lines 111, and the input end of the one of the plurality of multiplexers 125 is electrically connected to one of the plurality of fan-out wires 1201. Further, a distance F between the orthographic projection of any one of the plurality of scan signal lines 124 on the plane where the base substrate 10 is located and the orthographic projections of the plurality of multiplexers 125 on the plane where the base substrate 10 is located may be greater than or equal to 4 μm.

In this case, there is a relatively large distance between one of the plurality of scan signal lines 124 and one of the plurality of multiplexers 125. It is to be understood that the plurality of scan signal lines 124 provide scan signals in real time when displaying, and these scan pulse signals may cause electromagnetic interference to the plurality of multiplexers 125 to some extent when the distance is relatively short. In this embodiment of the present disclosure, one of the plurality of scan signal lines 124 is disposed to maintain a distance of 4 μm or more from one of the plurality of multiplexers 125 when extending in the non-display region 120, which can effectively weaken the influence of the scan pulse signals on the plurality of multiplexers 125, so that the plurality of multiplexers 125 normally strobe the data signal lines 111 and transmit data signals to the plurality of data signal lines 111. It is to be noted that the positional relationships between the plurality of scan signal lines 124 and the plurality of multiplexers 125 are not limited to the above embodiment shown in FIG. 21, and may be applied to any other embodiment of the present disclosure under the premise that the schemes do not conflict.

As is known from the above embodiments, the display panel targeted by the present disclosure may be a standard shape such as a circle, an ellipse, a rectangle, a rectangle with fillets, or the like, or may be a special-shape display panel. FIG. 23 is a structure diagram of another display panel according to an embodiment of the present disclosure. Referring to FIG. 23, this embodiment of the present disclosure may be applied to a special-shape display panel.

The special-shape display panel includes a display region 110 and a non-display region 120 surrounding the display region 110. The non-display region 120 further includes a bonding region 122. The bonding region 122 includes a plurality of bonding pads. The plurality of bonding pads are arranged sequentially along the first direction 1. The display region 110 includes a first display region 1101 and a second display region 1102. The first display region 1101 is located on one side of the second display region 1102 farther away from the bonding region 122. In the first direction 1, the width of the first display region 1101 is greater than the width of the second display region 1102.

As shown in FIG. 23, it is to be noted that the first display region 1101 and the second display region 1102 are only used to represent that the lateral width of a partial region (defined as the first display region 1101) in the display region of the display panel is greater than the lateral width of an adjacent partial region (defined as the second display region 1102) close to the bonding region 122. It is to be understood that in this case, the lateral edge region of the first display region 1101 protrudes from the edge of the first display region 1101, and data signals required by pixel units in this protruding portion when performing display driving may be provided only by fan-out wires 1201 disposed in the non-display region 120 on the lateral side. It is clear that the fan-out wires 1201 necessarily intersect scan signal lines 124 laterally extending by projection. Based on this, in this embodiment of the present disclosure, wire widths of the fan-out wires and the scan signal lines which intersect by projection in the non-display region of the special-shape display panel can be designed to prevent the projection intersecting from influencing the actually obtained wire widths and causing an open circuit. The design of the wire widths of the fan-out wires and scan signal lines has been described in the above embodiments. Repetition is not made here.

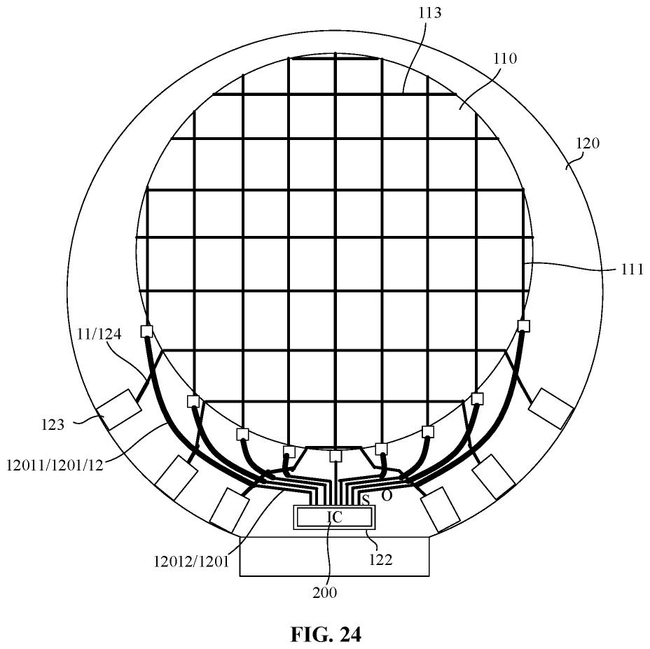

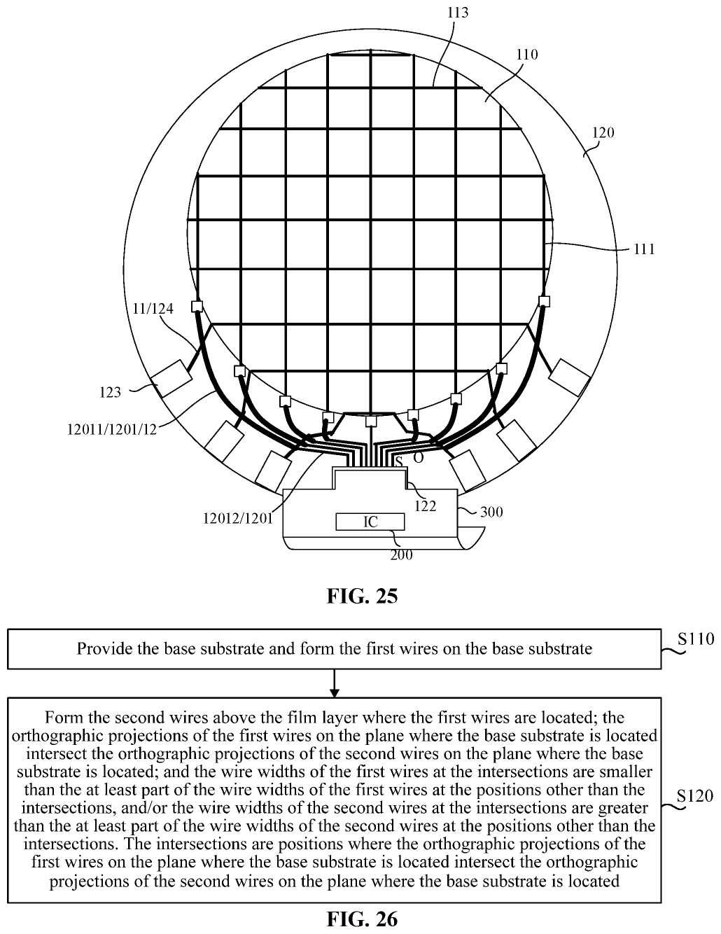

Based on the same invention concept, this embodiment of the present disclosure also provides a display device and a manufacturing method of a display panel. FIG. 24 and FIG. 25 are structure diagrams of two display devices according to an embodiment of the present disclosure. Referring to FIG. 24 and FIG. 25, the display device includes any one of display panels according to the above-described embodiments. Therefore, the display device according to this embodiment of the present disclosure has the corresponding beneficial effects of the display panel according to this embodiment of the present disclosure. Repetition is not made here. Exemplarily, the display device may be a mobile phone, a computer, a smart wearable device (for example, a smartwatch), an onboard display device, or other electronic devices, which is not limited in this embodiment of the present disclosure.

In an embodiment, referring to FIG. 24, the display device further includes a driver chip 200. A non-display region 120 of the array substrate in the display panel includes a bonding region 122. The bonding region 122 includes a plurality of bonding pads (not shown). The non-display region 120 includes a fan-out region. The fan-out region includes a plurality of fan-out wires 1201. The plurality of fan-out wires 1201 are electrically connected to the plurality of bonding pads in one-to-one correspondence. The driver chip 200 is bonded to the plurality of bonding pads.

Referring to FIG. 25, in another embodiment of the present disclosure, the display device may further include a flexible printed circuit board 300 and a driver chip 200 bonded to the flexible printed circuit board 300. A non-display region 120 of the array substrate in the display panel includes a bonding region 122. The bonding region 122 includes a plurality of bonding pads (not shown). One end of the flexible printed circuit board 300 is bonded to the plurality of bonding pads, and the other end of the flexible printed circuit board 300 is bent to one side of the array substrate facing away from the plurality of bonding pads.

It is to be understood that the arrangement of the driver chip 200 on the non-display region 120 of the display panel or the arrangement of the driver chip 200 on the flexible printed circuit board 300 is only the design manner of the driver chip 200. The arrangement of the driver chip 200 on the flexible printed circuit board 300 can save the space when the driver chip 200 is disposed on the display panel, thereby being conducive to shortening the longitudinal length of the lower bezel of the display panel, that is, the design of a narrow bezel is conducive. For the arrangement of the driver chip 200 on the non-display region of the display panel, the flexible printed circuit board still needs to be bonded to the non-display region of the display panel. In the above two design schemes, the flexible printed circuit board is used to transmit corresponding control signals to the driver chip 200, and then the driver chip 200 provides corresponding data signals, drive signals, or the like to signal lines such as data lines and gate lines in the display region.

FIG. 26 is a flowchart of a manufacturing method of a display panel according to an embodiment of the present disclosure. Referring to FIG. 26, the manufacturing method of the display panel is used to manufacture the display panel according to any of the above embodiments. The method includes the two steps below.

In S110, the base substrate is provided and the first wires are formed on the base substrate.

In S120, the second wires are formed above the film layer where the first wires are located. The orthographic projections of the first wires on the plane where the base substrate is located intersect the orthographic projections of the second wires on the plane where the base substrate is located. The wire widths of the first wires at the intersections where the orthographic projections of the first wires on the plane where the base substrate is located intersect the orthographic projections of the second wires on the plane where the base substrate is located are smaller than the at least part of the wire widths of the first wires at the positions other than the intersections, and/or the wire widths of the second wires at the intersections where the orthographic projections of the second wires on the plane where the base substrate is located intersect the orthographic projections of the second wires on the plane where the base substrate is located are greater than the at least part of the wire widths of the second wires at the positions other than the intersections.

It is to be understood that the above manufacturing method only represents the core idea of the present disclosure. For any display panel according to the embodiments of the present disclosure, the corresponding detailed manufacturing method is also included within the protection scope of the embodiments of the present disclosure, and will not be detailed herein.

Similarly, based on the same concept, an embodiment of the present disclosure also provides a mask. The mask is used to manufacture the first wires or the second wires of any of the display panels according to the embodiments of the present disclosure. The mask includes a light-transmissive region. The light-transmissive region includes a first light-transmissive subregion and a second light-transmissive subregion. The first light-transmissive subregion is used for manufacturing of the first wires at the intersections, and the second light-transmissive subregion is used for manufacturing of the first wires at the positions other than the intersections. A width of the first light-transmissive subregion in a direction perpendicular to an extension direction of the first light-transmissive subregion is smaller than a width of at least part of the second light-transmissive subregion in a direction perpendicular to an extension direction of the second light-transmissive subregion. Alternatively, the first light-transmissive subregion is used for manufacturing of the second wires at the intersections, and the second light-transmissive subregion is used for manufacturing of the second wires at the positions other than the intersections. A width of the first light-transmissive subregion in a direction perpendicular to an extension direction of the first light-transmissive subregion is greater than a width of at least part of the second light-transmissive subregion in a direction perpendicular to an extension direction of the second light-transmissive subregion.

As described above, this embodiment of the present disclosure provides a mask for the case in which the wire widths of the wires in the upper film layer may be influenced in the manufacturing process when the projections of the first wires of the display panel located in the lower film layer intersect the projection of the upper film layer. The mask may be used for manufacturing of the first wires. In an embodiment, the wire widths of the first light-transmissive subregion corresponding to the intersections of the wires in the mask may be appropriately reduced compared with the original design value. Therefore, the wire widths of the first wires at the intersections may be reduced, thereby weakening the reflection of the first wires during the exposure process and avoiding the influence of the overexposure amount on the wire widths of the wires in the upper layer. In this case, the wire widths of the first light-transmissive subregion for forming the first wires at the intersections are smaller than wire widths of the second light-transmissive subregion for forming the first wires at the positions other than the intersections.

This embodiment of the present disclosure provides another mask for the case in which the wire widths of the second wires may be influenced by the wires in the lower film layer in the manufacturing process when the projections of the second wires of the display panel located in the upper film layer intersect the projection of the lower film layer. The mask may be used for the manufacturing of the second wires. In an embodiment, the wire widths of the first light-transmissive subregion corresponding to the wire intersections in the mask may be appropriately increased compared with the original design value, and the wire widths of the second wires at the intersections may be increased, thereby compensating for the influence of the increased exposure amount of the wires in the lower layer on the wire widths of the wires in the upper layer. In this case, the wire widths of the first light-transmissive subregion for forming the second wires at the intersections are greater than the wire widths of the second light-transmissive subregion for forming the second wires at the positions other than the intersections.

It is to be noted that the mask according to this embodiment of the present disclosure may be used for manufacturing of the wires having projection intersecting in the display region or the non-display region of the display panel, and the wires may not be limited to fan-out wires, scan signal lines, touch signal lines, and the like mentioned in the embodiments of the present disclosure. The specific wire type, material, and the like are not limited.

It is to be noted that the preceding are only alternative embodiments of the present disclosure and technical principles used therein. It is to be understood by those skilled in the art that the present disclosure is not limited to the embodiments described herein. For those skilled in the art, various apparent modifications, adaptations, combinations, and substitutions can be made without departing from the scope of the present disclosure. Therefore, while the present disclosure has been described in detail via the preceding embodiments, the present disclosure is not limited to the preceding embodiments and may include more equivalent embodiments without departing from the inventive concept of the present disclosure. The scope of the present disclosure is determined by the scope of the appended claims.

What is claimed is:

1. A display panel comprising an array substrate, wherein the array substrate comprises a base substrate and first wires and second wires located on one side of the base substrate, wherein a film layer where the first wires are located is located between the base substrate and a film layer where the second wires are located; and
orthographic projections of the first wires on a plane where the base substrate is located intersect orthographic projections of the second wires on the plane where the base substrate is located; and wire widths of the first wires at intersections are smaller than at least part of wire widths of the first wires at positions other than the intersections, wherein the intersections are positions where the orthographic projections of the first wires on the plane where the base substrate is located intersect the orthographic projections of the second wires on the plane where the base substrate is located; and/or
wire widths of the second wires at intersections are greater than at least part of wire widths of the second wires at positions other than the intersections, wherein the intersections are positions where the orthographic projections of the first wires on the plane where the base substrate is located intersect the orthographic projections of the second wires on the plane where the base substrate is located.

2. The display panel according to claim 1, wherein one first wire of the first wires comprises a first subwire and a second subwire, and one second wire of the second wires comprises a third subwire and a fourth subwire;
wherein an orthographic projection of the first subwire on the plane where the base substrate is located intersects an orthographic projection of the third subwire on the plane where the base substrate is located; and a wire width of the first subwire is smaller than a wire width of the second subwire, and/or a wire width of the third subwire is greater than a wire width of the fourth subwire.

3. The display panel according to claim 2, wherein the one first wire further comprises a fifth subwire, a first end of the fifth subwire is connected to the first subwire, a second end of the fifth subwire is connected to the second subwire, a wire width of the first end of the fifth subwire is equal to the wire width of the first subwire, a wire width of the second end of the fifth subwire is equal to the wire width of the second subwire, and a wire width of the fifth subwire gradually increases from the first end of the fifth subwire to the second end of the fifth subwire; and
the one second wire further comprises a sixth subwire, a first end of the sixth subwire is connected to the third subwire, a second end of the sixth subwire is connected to the fourth subwire, a wire width of the first end of the sixth subwire is equal to the wire width of the third subwire, a wire width of the second end of the sixth subwire is equal to the wire width of the fourth subwire, and a wire width of the sixth subwire gradually decreases from the first end of the sixth subwire to the second end of the sixth subwire.

4. The display panel according to claim 1, wherein the display panel comprises a display region and a non-display region surrounding the display region, and the first wires and the second wires are both located in the non-display region.

5. The display panel according to claim 4, wherein the non-display region comprises a fan-out region, the fan-out region comprises a plurality of fan-out wires, and at least part of the plurality of fan-out wires comprise the first wires or the second wires.

6. The display panel according to claim 5, wherein
in response to the plurality of fan-out wires comprising the first wires, wire widths of the plurality of fan-out wires at the intersections are smaller than at least part of wire widths of the plurality of fan-out wires at the positions other than the intersections; or
in response to the plurality of fan-out wires comprising the second wires, wire widths of the plurality of fan-out wires at the intersections are greater than at least part of wire widths of the plurality of fan-out wires at the positions other than the intersections.

7. The display panel according to claim 5, wherein the fan-out region comprises a first fan-out region and a second fan-out region, and wiring density of the plurality of fan-out wires in the first fan-out region is greater than wiring density of the plurality of fan-out wires in the second fan-out region; and
in response to the plurality of fan-out wires comprising the first wires, projections of the first wires at least partially intersect a projection of the second fan-out region, and projections of the second wires at least partially intersect projections of the first wires in the second fan-out region; or
in response to the plurality of fan-out wires comprising the second wires, projections of the second wires at least partially intersect a projection of the second fan-out region, and projections of the first wires at least partially intersect projections of the second wires in the second fan-out region.

8. The display panel according to claim 7, wherein the fan-out region further comprises a third fan-out region, and wiring density of the plurality of fan-out wires in the third fan-out region is between the wiring density of the plurality of fan-out wires in the first fan-out region and the wiring density of the plurality of fan-out wires in the second fan-out region.

9. The display panel according to claim 8, wherein the first fan-out region comprises first fan-out wires, the second fan-out region comprises second fan-out wires, and the third fan-out region comprises third fan-out wires; wherein one of at least part of the first fan-out wires is electrically connected to a second fan-out wire corresponding to the one of at least part of the first fan-out wires through a third fan-out wire corresponding to the one of at least part of the first fan-out wires; and
a wire width of one of the third fan-out wires is greater than a wire width of one of the first fan-out wires and smaller than or equal to a wire width of one of the second fan-out wires.

10. The display panel according to claim 7, wherein the second fan-out region comprises second fan-out wires; the non-display region further comprises a bonding region, and the bonding region comprises a plurality of bonding pads; and
the first fan-out region comprises first fan-out wires, one of at least part of the first fan-out wires comprises a straight line portion and an oblique line portion, one end of the straight line portion is electrically connected to a respective one of the plurality of bonding pads in one-to-one correspondence, the other end of the straight line portion is electrically connected to one end of the oblique line portion in one-to-one correspondence, and the other end of the oblique line portion is electrically connected to one of the second fan-out wires.

11. The display panel according to claim 5, wherein the non-display region further comprises a bonding region, and the bonding region comprises a plurality of bonding pads;
the display region further comprises a plurality of data signal lines or a plurality of touch signal lines; and
one end of one of the plurality of fan-out wires is connected to one of the plurality of data signal lines or one of the plurality of touch signal lines, and the other end of the one of the plurality of fan-out wires is connected to one of the plurality of bonding pads.

12. The display panel according to claim 5, wherein the array substrate further comprises a first metal layer and a second metal layer stacked on one side of the base substrate, and at least part of the plurality of fan-out wires are located in the second metal layer.

13. The display panel according to claim 5, wherein the array substrate further comprises a first metal layer, a second metal layer, and a third metal layer stacked on one side of the base substrate, and at least part of the plurality of fan-out wires are located in the second metal layer or the third metal layer.

14. The display panel according to claim 11, wherein the non-display region further comprises a plurality of shift registers and a plurality of scan signal lines, the display region comprises a plurality of gate signal lines, one end of one of the plurality of scan signal lines is connected to one of the plurality of shift registers, and the other end of the one of the plurality of scan signal lines is connected to one of the plurality of gate signal lines; and at least part of the plurality of scan signal lines comprise the first wires or the second wires.

15. The display panel according to claim 1, wherein the display panel is a special-shaped display panel.

16. The display panel according to claim 15, wherein the display panel comprises a display region and a non-display region surrounding the display region, the non-display region further comprises a bonding region, the bonding region comprises a plurality of bonding pads, and the plurality of bonding pads are sequentially arranged along a first direction; and
the display region comprises a first display region and a second display region, and the first display region is located on one side of the second display region farther away from the bonding region; and in the first direction, a width of the first display region is greater than a width of the second display region.

17. A display device, comprising a display panel;
wherein the display panel comprises an array substrate, the array substrate comprises a base substrate and first wires and second wires located on one side of the base substrate, and a film layer where the first wires are located is located between the base substrate and a film layer where the second wires are located; and
orthographic projections of the first wires on a plane where the base substrate is located intersect orthographic projections of the second wires on the plane where the base substrate is located; and wire widths of the first wires at intersections are smaller than at least part of wire widths of the first wires at positions other than the intersections, wherein the intersections are positions where the orthographic projections of the first wires on the plane where the base substrate is located intersect the orthographic projections of the second wires on the plane where the base substrate is located; and/or
wire widths of the second wires at intersections are greater than at least part of wire widths of the second wires at positions other than the intersections, wherein the intersections are positions where the orthographic projections of the first wires on the plane where the base substrate is located intersect the orthographic projections of the second wires on the plane where the base substrate is located.

18. The display device according to claim 17, wherein the display device further comprises a driver chip, a non-display region of the array substrate in the display panel comprises a bonding region, and the bonding region comprises a plurality of bonding pads; the non-display region comprises a fan-out region, the fan-out region comprises a plurality of fan-out wires, and the plurality of fan-out wires are electrically connected to the plurality of bonding pads in one-to-one correspondence; and the driver chip is bonded to the plurality of bonding pads.

19. The display device according to claim 17, wherein the display device further comprises a flexible printed circuit board and a driver chip bonded to the flexible printed circuit board, a non-display region of the array substrate in the display panel comprises a bonding region, and the bonding region comprises a plurality of bonding pads; and one end of the flexible printed circuit board is bonded to the plurality of bonding pads, and the other end of the flexible printed circuit board is bent to one side of the array substrate facing away from the plurality of bonding pads.

20. A mask, the mask being configured for manufacturing of first wires or second wires in a display panel, and the mask comprising a light-transmissive region;
wherein the display panel comprises an array substrate, the array substrate comprises a base substrate and the first wires and the second wires located on one side of the base substrate, and a film layer where the first wires are located is located between the base substrate and a film layer where the second wires are located; and
orthographic projections of the first wires on a plane where the base substrate is located intersect orthographic projections of the second wires on the plane where the base substrate is located; and wire widths of the first wires at intersections are smaller than at least part of wire widths of the first wires at positions other than the intersections, wherein the intersections are positions where the orthographic projections of the first wires on the plane where the base substrate is located intersect the orthographic projections of the second wires on the plane where the base substrate is located; and/or
wire widths of the second wires at intersections are greater than at least part of wire widths of the second wires at positions other than the intersections, wherein the intersections are positions where the orthographic projections of the first wires on the plane where the base substrate is located intersect the orthographic projections of the second wires on the plane where the base substrate is located;
wherein the light-transmissive region comprises a first light-transmissive subregion and a second light-transmissive subregion; and
the first light-transmissive subregion is configured for manufacturing of the first wires at the intersections, and the second light-transmissive subregion is configured for manufacturing of the first wires at the positions other than the intersections; and a width of the first light-transmissive subregion in a direction perpendicular to an extension direction of the first light-transmissive subregion is smaller than a width of at least part of the second light-transmissive subregion in a direction perpendicular to an extension direction of the second light-transmissive subregion; or
the first light-transmissive subregion is configured for manufacturing of the second wires at the intersections, and the second light-transmissive subregion is configured for manufacturing of the second wires at the positions other than the intersections; and a width of the first light-transmissive subregion in a direction perpendicular to an extension direction of the second light-transmissive subregion is greater than a width of at least part of the second light-transmissive subregion in a direction perpendicular to an extension direction of the second light-transmissive subregion.
